(19) United States
(12) Patent Application Publication
(10) Pub. No.: US 2005/0083144 A1
(43) Pub. Date: Apr. 21, 2005

(54) Adjustable voltage control oscillator

(76) Inventor: Chao-Hsin Lu, Dayuan Township (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/963,160

(22) Filed: Oct. 12, 2004

(30) Foreign Application Priority Data
Oct. 17, 2003 (TW) 92128945

(51) Int. Cl. H03B 1/00

(52) U.S. Cl. 331/185

(57) ABSTRACT

A voltage control oscillator (VCO) whose gain coefficient is adjustable outputs a clock signal according to a control voltage. The VCO includes a replica bias unit, at least a delay cell, coupled to the replica bias unit, and a loading circuit. The replica bias unit outputs a first operational voltage according to the control voltage. The delay cell includes a voltage control delay line for outputting an output differential signal according to an input differential signal. The frequency of the output differential signal is adjusted by changing the impedance of the loading circuit.

This application claims the benefit of Taiwan application Serial No. 92128945, filed Oct. 17, 2003, the subject matter of which is incorporated herein by reference.

### BACKGROUND OF THE INVENTION

1. Field of the Invention

The invention relates in general to a voltage control oscillator (VCO), and more particularly to a VCO whose gain coefficient can be adjusted by changing the impedance of the delay cell.

2. Description of the Related Art

VCO is an integrated circuit in which the output signal frequency can be adjusted by controlling the input voltage, and is widely applied to the phase locked loop (PLL), the delay locked loop (DLL), and the wireless communication products.

Referring to FIG. 1A, a structure diagram of the conventional VCO is shown. The VCO 100 generally includes a replica bias unit 110 and a number of voltage control delay lines (VCDLs) 120. The replica bias unit 110 receives an input control voltage Vc, and accordingly outputs bias voltages Vbp and Vbn, which are respectively used as the high voltage level VH and the low voltage level VL of the VCDLs 120. The VCDLs are connected to each other in serial to form a feedback circuit and output a clock signal Fo.

Referring to FIG. 1B, a circuit diagram of the VCDL 120 in FIG. 1A is shown. The VCDL 120 is a differential delay cell and is formed by seven transistors M1 to M7. The VCDL 120 includes a positive input terminal ip, a negative input terminal in, a positive output terminal op, and a negative output terminal on. The input terminals ip and in are respectively coupled to the gate electrodes of the transistors M1 and M2, and the output terminals op and on are respectively coupled to the drain electrodes of the transistors M2 and M1. The source electrodes of the transistors M1 and M2 are coupled to the drain electrode of the transistor M3, and the gate electrode and the source electrode of the transistor M3 are respectively coupled to the bias voltage Vbp and the voltage VDD. Moreover, the transistors M4, M6, and the transistors M5, M7, forming symmetric loading circuits, are respectively coupled to the drain electrodes of the transistors M1 and M2. The bias voltage Vbn is input to the gate electrodes of the transistors M6 and M7.

The VCO 100 is controlled by the voltage Vc and generates the clock signal Fo via the feedback circuit formed by the above-mentioned VCDLs 120. The frequency f of the clock signal Fo is linearly proportional to the control voltage Vc, which is measured relative to the ground level, as shown in FIG. 1C. The slope Δf/ΔVc is defined as the gain coefficient Kvco of the VCO 100. Due to the semiconductor process variation and other factors, the gain coefficients Kvco of different VCOs 100 are not always the same.

As shown in FIG. 1D, the curves FF, TT, and SS respectively represent a short delay time status (Fast), a common delay time status (Typical), and a long delay time status (Slow) of the VCO 100. When the gain coefficient Kvco of the VCO 100 is small, such as the slope of the curve SS, the frequency of the output signal cannot reach to the target range TR under the limited range of the control voltage Vc as shown in FIG. 1E, wherein the target region TR filled by the oblique lines represents the required output frequency range. When the gain coefficient Kvco is large, such as the slope of the curve FF, the output signal frequency f has high sensitivity to the variation of the control voltage Vc as shown in FIG. 1F. Consequently, the effects of the noise coupled to the control voltage Vc increases, and may thus cause the system's error operation. Therefore, the correction to the gain coefficient of the VCO 100 has to be made in order to prevent the error operation.

### SUMMARY OF THE INVENTION

It is therefore an object of the invention to provide an adjustable VCO whose gain coefficient can be adjusted by changing the impedance of the delay cell.

It is therefore another object of the invention to provide an adjustable VCO whose output frequency range can be controlled by changing the impedance of the delay cell.

The invention achieves the above-identified object by providing a VCO whose gain coefficient is adjustable. The VCO includes a replica bias unit, at least a delay cell coupled to the replica bias unit, and at least a loading circuit. The replica bias unit is used for outputting an operational voltage according to a control voltage. The delay cell is operated by the operational voltage and includes a VCDL for outputting an output differential signal according to an input differential signal, wherein the output differential signal can be adjusted by changing the impedance of the loading circuit.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1A is a structure diagram of a conventional VCO.

FIG. 1B is a circuit diagram of the VCDL in FIG. 1A.

FIG. 1C is a diagram showing a characteristic curve representing the relation between the output signal frequency and the control voltage of a conventional VCO.

FIG. 1D is a diagram showing different characteristic curves of different conventional VCOs influenced by the process variation.

FIG. 1E is a diagram showing a characteristic curve SS outside a target region TR due to a process variation.

FIG. 1F is a diagram showing a characteristic curve FF sensitive to the control voltage due to a process variation.

FIG. 2 is a schematic diagram of the VCO according to an embodiment of the invention.

FIG. 3A is a diagram of the delay cell in FIGL 2.

FIG. 3B is a schematic diagram showing a VCO characteristic curve SS adjusted to a normal curve Ta according to an embodiment of the invention.

FIG. 3C is a schematic diagram showing a VCO characteristic curve FF adjusted to a normal curve Tb according to an embodiment of the invention.

FIG. 4 is a diagram showing the adjustment of the characteristic curve for matching the required VCO output signal frequency range under the limited control voltage according to an embodiment of the invention.

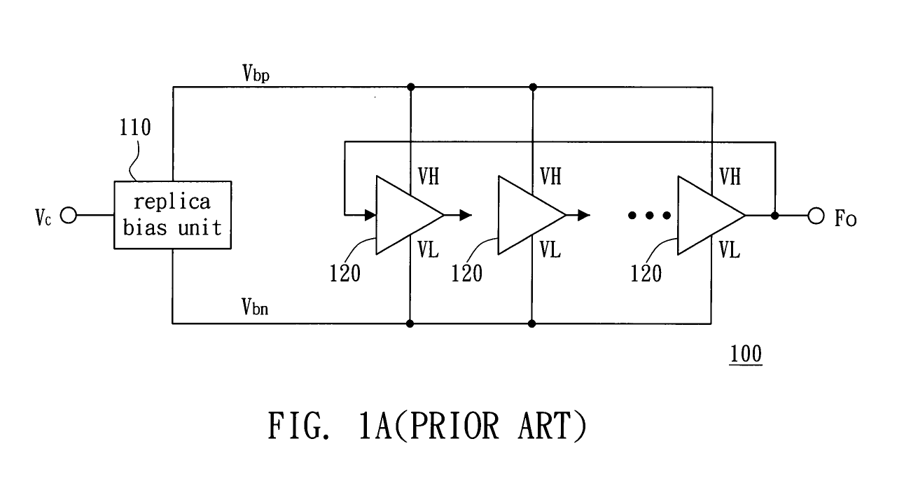

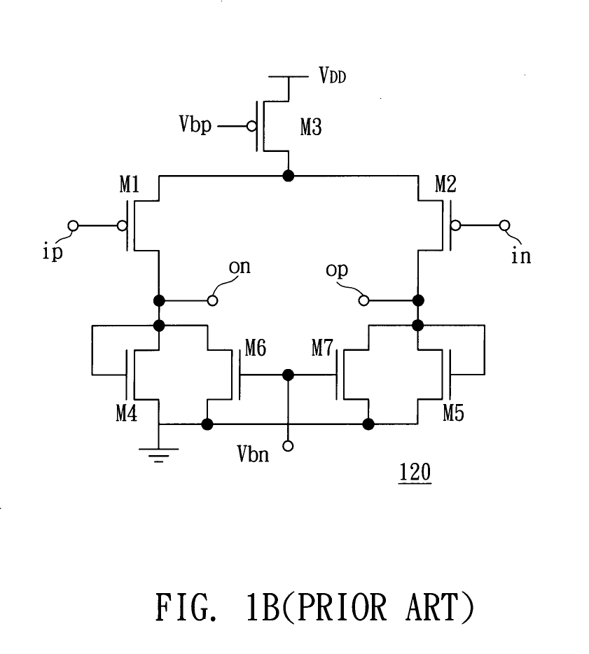

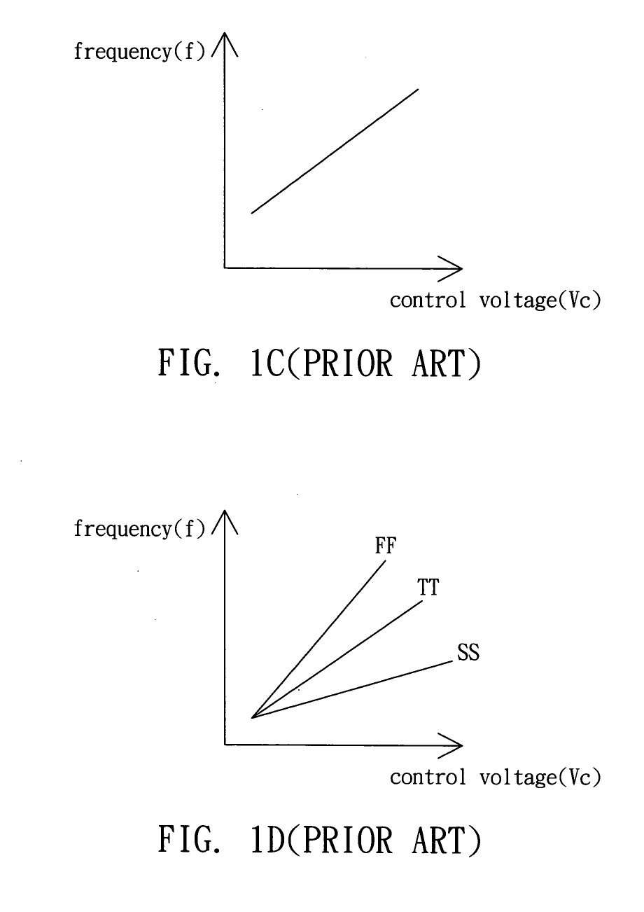

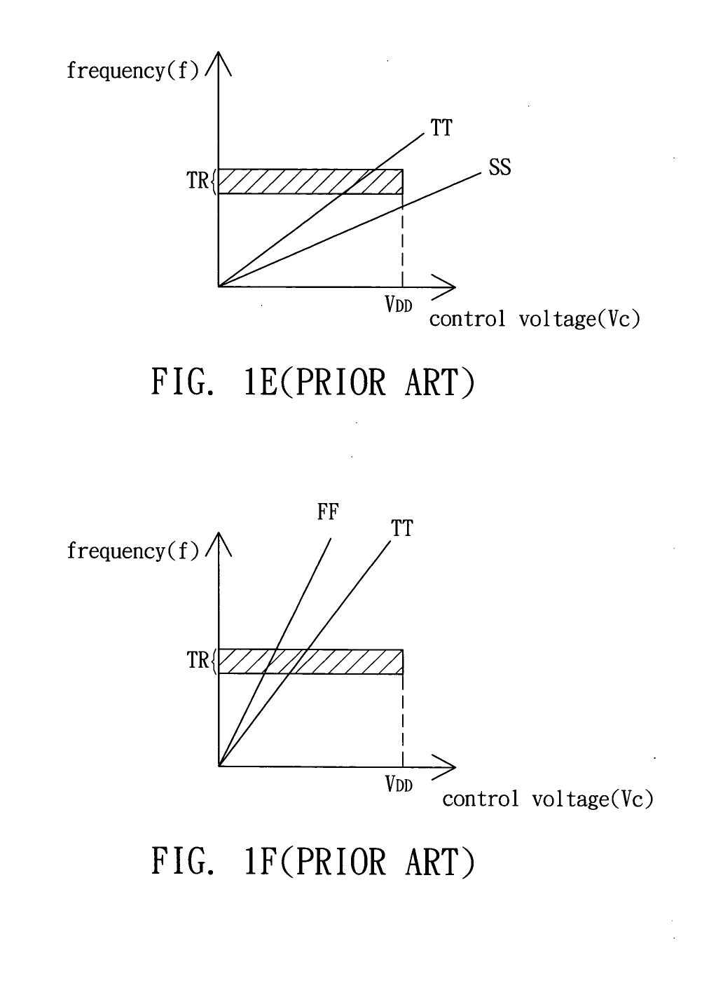

### DETAILED DESCRIPTION OF THE INVENTION

According to an embodiment of the invention, the VCO gain coefficient can be adjusted by changing the impedance coupled to the output terminal of the VCDL of the VCO. Therefore the VCO can be adjusted to work normally regardless of the process variation.

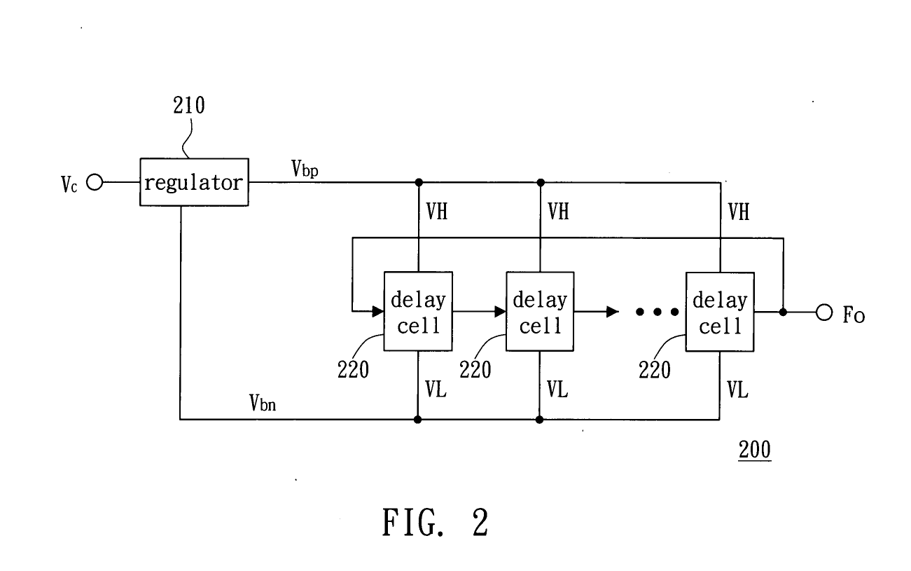

Referring to FIG. 2, a schematic diagram of the VCO according to an embodiment of the invention is shown. The VCO 200 includes a regulator 210 and a number of delay cells 220. The regulator 210, which can be a replica bias unit or an operational amplifier, receives the control voltage Vc and accordingly outputs the bias voltages Vbp and Vbn, so as to providing the common high voltage level VH and the common low voltage level VL for the delay cells 220. The delay cells 220 are coupled in serial to form a feedback circuit and output a clock signal Fo.

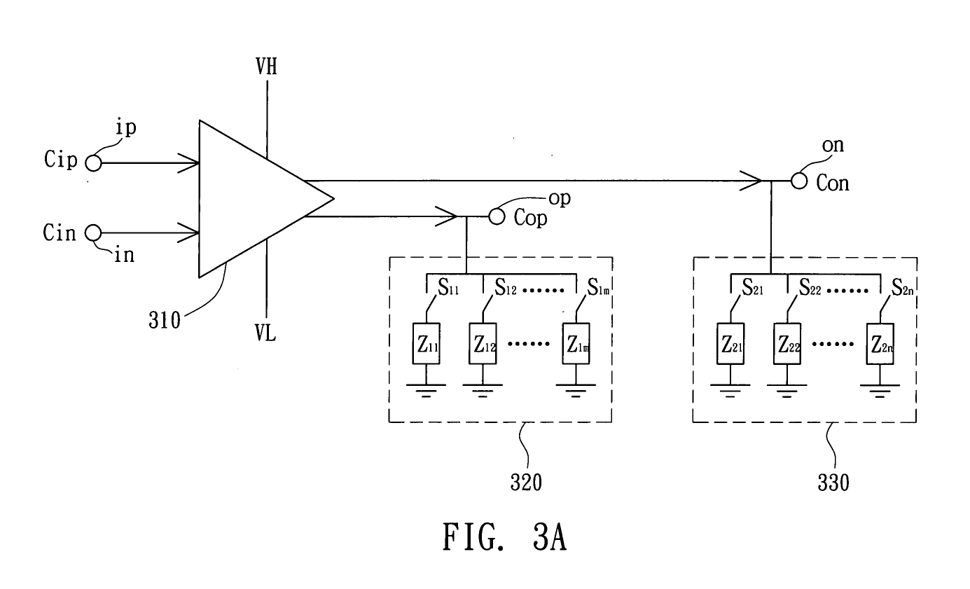

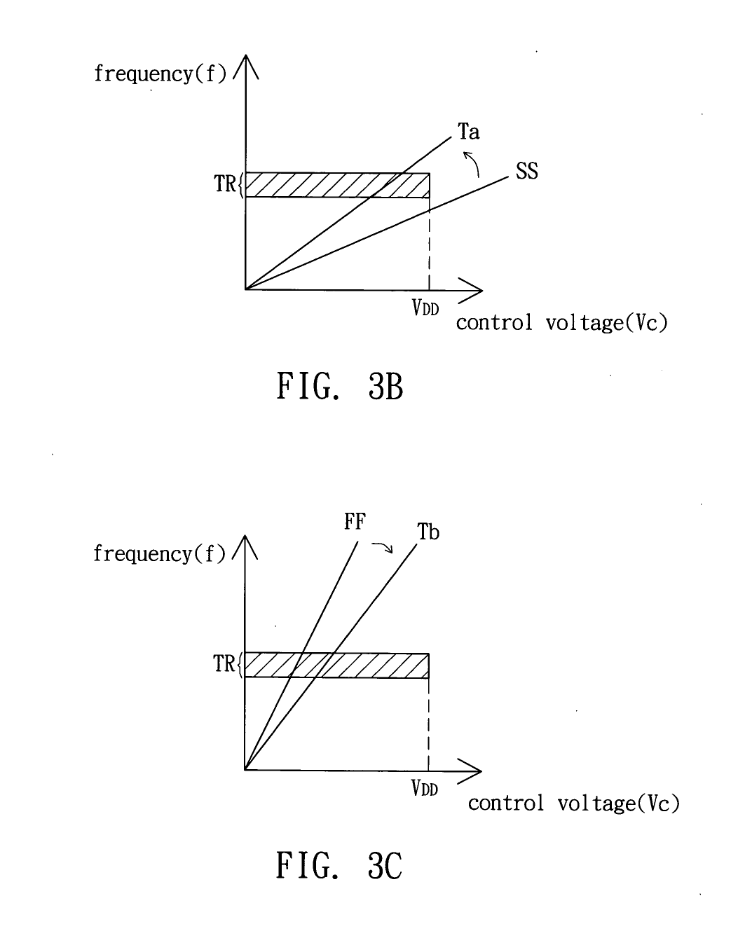

Referring to FIG. 3A, a diagram of the delay cell 220 illustrated in FIG. 2 is shown. The delay cell 220 includes a VCDL 310, a first loading circuit 320, and a second loading circuit 330. The VCDL 310 includes a positive and a negative input terminals ip and in for respectively receiving differential signals Cip and Cin, and a positive and a negative output terminals op and on for respectively outputting differential signals Cop and Con. The frequency of the output signals Cip and Cop of the VCDL 310 can be adjusted by controlling the high voltage level VH, which is equal to Vbp, and the low voltage level VL, which is equal to Vbn. In another embodiment of the invention, the VCDL may receive and output a single input signal and a single output signal, respectively.

Please refer to FIG. 3A, the first loading circuit 320, coupled to the positive output terminal op, includes m impedances Z11 to Z1m coupled in parallel, wherein m is an positive integer. The impedances Z11 to Z1m are respectively coupled to the positive output terminal op through the switches S11 to S1m. The second loading circuit 330, coupled to the negative output terminal on, includes n impedances Z21 to Z2n connected in parallel. The impedances Z21 to Z2n are respectively coupled to the negative output terminal on through the switches S21 to S2n. The impedances Z11 to Z1m and Z21 to Z2n can be resistors or transistors. Consequently, the frequency of the output signals of the VCO 200 can be adjusted by changing the delay time coefficient of the delay cell 220, that is, through adjusting the impedances of the first loading circuit 320 or the second loading circuit 330 or both. Moreover, each of the switches S11 to S1m and S21 to S2n may be coupled to a calibration device (not shown) which determines the turned-on or turned-off status of each switch, so as to determine the impedances of the first and the second loading circuits 320 and 330.

Besides, in another embodiment of the invention, the switches may be respectively coupled between the impedances and the ground level. In addition, the impedances may be coupled in serial or both of parallel and serial.

When the gain coefficient Kvco of the VCO 200 is too small and the characteristic curve defined by the output signal frequency f and the control voltage Vc is close to the curve SS, the gain coefficient Kvco can be increased by reducing the impedance of the first and the second loading circuits 320 and 330 of each delay cell 220. Due to the impedances Z11 to Z1m and Z21 to Z2n respectively coupled in parallel, when the number of the turn-on switches among the switches S11 to S1m and S21 to S2n is increased, the conduction resistances Ron of the positive and negative output terminals op and on of the corresponding delay cell 220 are reduced, such that the gain coefficient Kvco is enlarged. Therefore, the characteristic curve is lifted from the curve SS to the curve Ta and thus the frequency of the output signal Fo of the VCO 200 is inside the required frequency range TR as shown in FIG. 3B.

When the gain coefficient Kvco of the VCO 200 is too large and the characteristic curve is close to the curve FF, the gain coefficient Kvco can also be decreased by increasing the impedance of the first and the second loading circuits 320 and 330 of each delay cell 220. By increasing the number of the turn-off switches among the switches S11 to S1m and S21 to S2n, the conduction resistances Ron of the positive and negative output terminals op and on can be increased, and the gain coefficient Kvco can be reduced consequently. Therefore, the characteristic curve can be shifted from the curve FF to the curve Tb which is less sensitive to the control voltage Vc, such that the VCO 200 can be operated normally within the required frequency range TR as shown in FIG. 3C. By changing the loading impedance of the first and the second loading circuits 320 and 330, the gain coefficient can be adjusted to the required value.

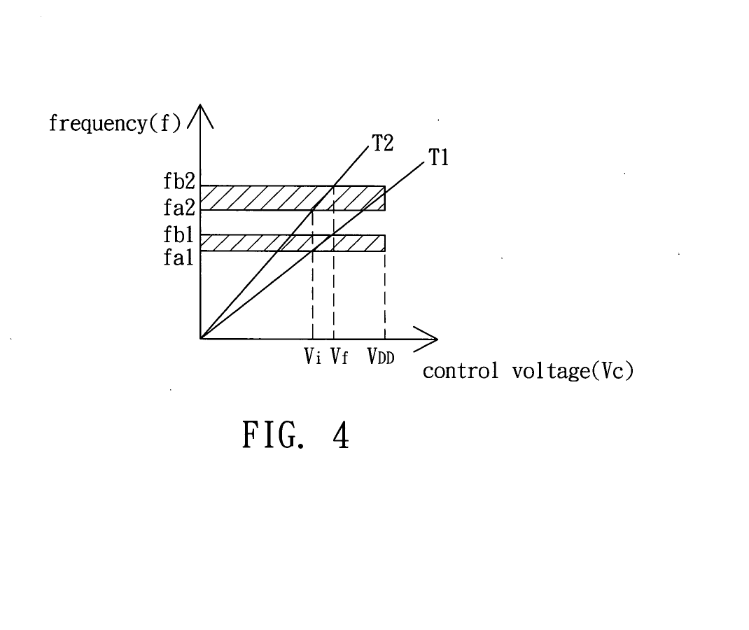

Furthermore, as shown in FIG. 4, under the limited control voltage Vc, such as between the voltage Vi and the voltage Vf, in terms of the characteristic curve T1, the frequency range of the signals generated by the VCO 200 is fa1 to fb1. The characteristic curve T1 can also be adjusted to the curve T2 by changing the number of the turn-on switches among the switches S11 to S1m and S21 to S2n and thereby the frequency range fa1 to fb1 can be adjusted to the frequency range fa2 to fb2. Therefore, the output signal frequency range of the VCO 200 can be modified.

According to the embodiment mentioned above, the adjustable VCO of the invention has the following advantages:

1. The gain coefficient of the VCO can be adjusted by changing the impedance of the loading circuit of the delay cell, so the required frequency range of the output clock signal can be obtained.

2. The VCO gain coefficient Kvco can be adjusted easily. Under the limited range of the control voltage, the characteristic curve of the output signals can be adjusted easily and the output frequency range of the VCO can be increased.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. An oscillator, for outputting a clock signal according to a control voltage, the oscillator comprising:
a regulator, for outputting an operational voltage according to the control voltage; and
at least a delay cell for receiving the operational voltage and outputting the clock signal, the delay cell comprising:
a loading circuit, wherein the frequency of the clock signal is adjustable by adjusting the impedance of the loading circuit.

2. The oscillator of claim 1, wherein the delay cell further comprises:
a voltage control delay line (VCDL) coupled to the loading circuit.

3. The oscillator of claim 1, wherein the loading circuit comprises:
at least one impedance element whose impedance is adjustable.

4. The oscillator of claim 3, wherein the impedance element is a transistor or a resistor coupled to a switch.

5. The oscillator of claim 1, wherein the loading circuit comprises:
a plurality of impedance elements coupled together; and
a plurality of switches respectively coupled to the impedance elements;
wherein each of the switches may be turned on or turned off and the impedance of the loading circuit is determined by the number of the turned-on switches.

6. The oscillator of claim 5, wherein at least two of the impedance elements are coupled in parallel or serial.

7. The oscillator of claim 5, wherein at least one of the impedance elements is a resistor.

8. The oscillator of claim 5, wherein at least one of the impedance elements is a transistor.

9. The oscillator of claim 1, wherein the regulator is a replica bias unit.

10. The oscillator of claim 1, wherein the regulator is an operational amplifier.

11. The oscillator of claim 1, further comprising:
a calibration device coupled to the loading circuit for determining the impedance of the loading circuit.

12. A delay cell, used in an oscillator, the delay cell comprising:
a voltage control delay line (VCDL); and
a loading circuit coupled to the VCDL, wherein the impedance of the loading circuit is adjustable.

13. The delay cell of claim 12, wherein the loading circuit comprises:
at least one impedance element whose impedance is adjustable.

14. The delay cell of claim 13, wherein the impedance element is a transistor or a resistor coupled to a switch.

15. The delay cell of claim 12, wherein the loading circuit comprises:
a plurality of impedance elements coupled together; and
a plurality of switches respectively coupled to the impedance elements;
wherein each of the switches may be turned on or turned off and the impedance of the loading circuit is determined by the number of the turned-on switches.

16. The delay cell of claim 15, wherein the impedance elements coupled in parallel, serial, or both.

17. The delay cell of claim 15, wherein at least one of the impedance elements is a resistor.

18. The delay cell of claim 15, wherein at least one of the impedance elements is a transistor.

19. The delay cell of claim 12, further comprising:
a calibration device coupled to the loading circuit for determining the impedance of the loading unit.
